(19) United States
(12) Patent Application Publication
(10) Pub. No.: US 2016/0159037 A1
(43) Pub. Date: Jun. 9, 2016

(54) HEAT DISSIPATING SHEET AND HEAT DISSIPATING STRUCTURAL BODY USING SAME

(71) Applicant: Panasonic Intellectual Property Management Co., Ltd., Osaka (JP)

(72) Inventors: YOSHIYA SAKAGUCHI, Kyoto (JP); MASAFUMI NAKAYAMA, Hokkaido (JP)

(21) Appl. No.: 14/778,583

(22) PCT Filed: Mar. 4, 2014
(86) PCT No.: PCT/JP2014/001164

§ 371 Date: Sep. 19, 2015

(30) Foreign Application Priority Data
Mar. 25, 2013 (JP) 2013-061413

(51) Int. Cl. B32B 9/04; H05K 1/18; H05K 7/20; B32B 7/02; B32B 9/00

(52) U.S. Cl. CPC B32B 9/045; B32B 7/02; B32B 9/007; H05K 7/20509; H05K 1/181; B32B 2307/302

(57) ABSTRACT

A heat dissipation sheet includes a thermally conductive resin sheet plastically deformable at 25° C., and a thermally conductive film bonded to the thermally conductive resin sheet and having a higher thermal conductivity than the thermally conductive resin sheet. The heat dissipation sheet has excellent heat dissipation characteristics.

### TECHNICAL FIELD

The present invention relates to a heat dissipation sheet used in electronic devices, and a heat dissipation structure including the sheet.

### BACKGROUND ART

With the increasing improvement in function and processing capability of electronic devices in recent years, electronic components such as semiconductor devices tend to generate more heat. To release or propagate heat generated in these heat-generating components so as to maintain their operating performance, reliability, and other properties, they are placed in contact with a thermally conductive sheet, which is formed by mixing resin and a thermally conductive filler and then curing the mixture. The “heat-generating component” means an electronic component that can generate heat.

An example of conventional techniques related to the present invention is shown in Patent Literature 1.

### CITATION LIST

### Patent Literature

PTL 1: Japanese Unexamined Patent Application Publication No. 2010-24371

### SUMMARY OF THE INVENTION

The heat dissipation sheet of the present invention includes a thermally conductive resin sheet plastically deformable at 25° C., and a thermally conductive film bonded to the resin sheet and having a higher thermal conductivity than the resin sheet.

The heat dissipation structure of the present invention includes a printed circuit board, an electronic component mounted on the component side of the circuit board, and a heat dissipation sheet formed on the circuit board so as to cover the electronic component. The heat dissipation sheet includes a thermally conductive resin sheet plastically deformable at 25° C., and a thermally conductive film bonded to the resin sheet and having a higher thermal conductivity than the resin sheet. The thermally conductive resin sheet has first to third portions on a side opposite to a side to which the thermally conductive sheet is bonded. The first portion is in contact with the component side of the circuit board. The second portion is in contact with the entire upper surface of the electronic component. The third portion is in contact with at least a half of the lateral sides of the electronic component.

The above-described configurations allow a heat dissipation sheet and a heat dissipation structure to have excellent heat dissipation characteristics.

### BRIEF DESCRIPTION OF DRAWINGS

FIG. 1 is a sectional view of a heat dissipation sheet according to an exemplary embodiment of the present invention.

FIG. 2 is a sectional view of a heat dissipation structure according to the exemplary embodiment of the present invention.

### DESCRIPTION OF EMBODIMENT

Conventional thermally conductive sheets have a high thermal resistance between themselves and a heat-generating component. Also, the sheets themselves do not have a thermal conductivity high enough to completely release or propagate heat. The thermal resistance caused by the contact between the heat-generating component and a thermally conductive sheet can be reduced by subjecting the component to a mixture of liquid resin with a thermally conductive filler, and curing the mixture. In this case, however, it is difficult to remove the component from the printed circuit board.

The heat dissipation sheet according to the exemplary embodiment of the present invention, which has been developed to solve the aforementioned conventional problems, will now be described with reference to drawings.

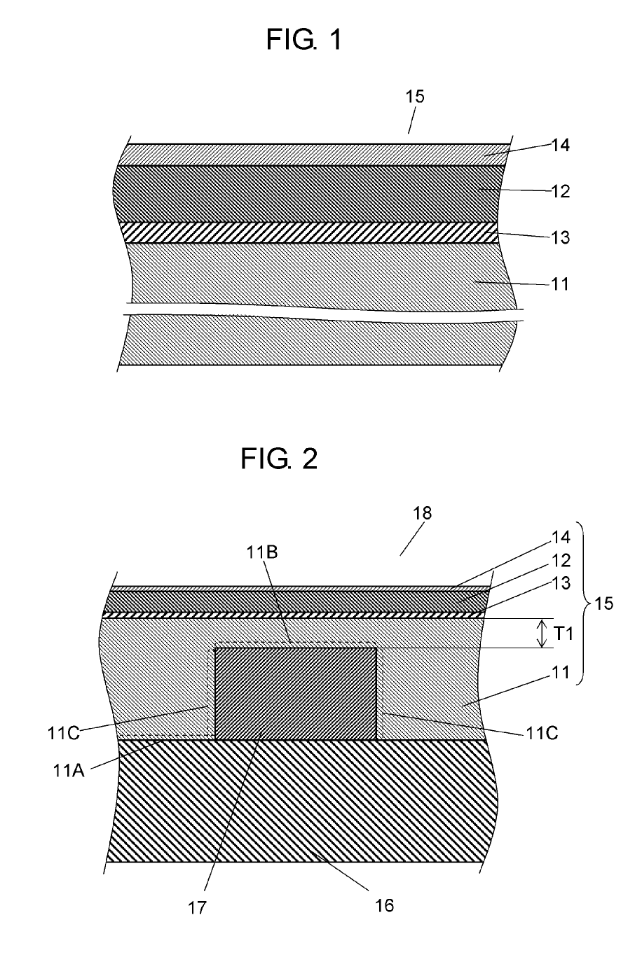

FIG. 1 is a sectional view of heat dissipation sheet 15 according to the exemplary embodiment of the present invention. Heat dissipation sheet 15 includes thermally conductive resin sheet 11, and thermally conductive film 12 bonded to the upper surface of sheet 11 via double-sided adhesive tape 13 with a thickness of, for example, 10 μm. More specifically, heat dissipation sheet 15 includes thermally conductive resin sheet 11, which is plastically deformable at room temperature (25° C.), and thermally conductive film 12 bonded to resin sheet 11. Resin sheet 11 is, for example, a styrene polymer sheet having a thickness of 1.3 mm. Thermally conductive film 12 is, for example, a graphite film having a thickness of 25 μm. Heat dissipation sheet 15 further includes protective film 14 having a thickness of, for example, 10 μm and bonded to the upper surface of film 12.

Thermally conductive resin sheet 11 is made of insulating material that is plastically deformable at 25° C. The term “plastically deformable” means to deform at a pressure of 0.5 MPa or less and to remain the deformed shape after the pressure is removed. In general, sheets made of resin such as styrene polymer are elastically deformed by that low pressure. In contrast, sheets made of resin mixed with a large amount of plasticizer are plastically deformable at 25° C. at a low pressure.

Thus, in heat dissipation sheet 15, one side of thermally conductive resin sheet 11 plastically deformable at 25° C. is bonded to one side of thermally conductive film 12 having a higher thermal conductivity than resin sheet 11. With this configuration, heat dissipation sheet 15 can be adhesively bonded to the surface of an object with heat dissipation characteristics and also have a high thermal conductivity, thereby providing excellent heat dissipation characteristics.

Thermally conductive resin sheet 11 has a thermal conductivity of 2 W/m·K. In actual practice, the thermal conductivity of resin sheet 11 is preferably at least 1 W/m·K because the higher the thermal conductivity, the more efficiently resin sheet 11 can propagate heat. It is, however, difficult to obtain a high thermal conductivity by a sheet made of only resin. For this reason, in heat dissipation sheet 15, thermally conductive film 12, which has a much higher thermal conductivity than resin sheet 11, is bonded to the upper surface of resin sheet 11. With this configuration, the heat propagated to resin sheet 11 can quickly diffuse to thermally conductive film 12 in the surface direction. This feature enables resin sheet 11 with a thermal conductivity as low as 2 W/m·K to quickly release or propagate the heat. Thermally conductive film 12 is made of material other than resin with preferably at least 100 times higher thermal conductivity than resin sheet 11. More specifically, the thermal conductivity of film 12 is preferably at least 100 W/m·K in the surface direction. This allows heat dissipation sheet 15 to have practically excellent heat dissipation characteristics in the surface direction.

Thermally conductive film 12 is preferably a pyrolytic graphite film, which has a thermal conductivity of 1600 W/m·K in the surface direction so as to ensure excellent heat dissipation characteristics.

Thermally conductive resin sheet 11 preferably has a thickness within a range from 0.5 mm to 2 mm, inclusive. Resin sheet 11 with a thickness within the range can be in close contact with a heat-generating electronic component such as an integrated circuit (IC) after plastic deformation, allowing heat dissipation sheet 15 to have excellent heat dissipation characteristics.

It is further preferable that insulating protective film 14 is bonded to the upper surface of thermally conductive film 12 as shown in FIG. 1.

Protective film 14 ensures the insulation of the surface of heat dissipation sheet 15 and also protects sheet 15 from external damage. Film 14 may be a double-sided adhesive tape so that sheet 15 can be connected to a housing or a heat sink so as to release or propagate heat efficiently.

The following is a description of a heat dissipation structure including heat dissipation sheet 15. FIG. 2 is a sectional view of heat dissipation structure 18 according to the exemplary embodiment of the present invention.

Heat dissipation structure 18 includes printed circuit board 16, heat-generating component 17 mounted on circuit board 16, and heat dissipation sheet 15, which covers circuit board 16 from over component 17. The upper surface of circuit board 16 is a component side on which component 17 is mounted. Component 17 is a heat-generating electronic component such as an IC. The component side of circuit board 16 is mounted with heat-generating component 17 and other electronic components. Component 17 has a height of, for example, about 1 mm.

Heat dissipation sheet 15 is formed by bonding the lower surface of film 12 to the upper surface of resin sheet 11, which is, for example, 1.3 mm thick. Resin sheet 11 is a styrene polymer sheet plastically deformable at room temperature, whereas film 12 is a pyrolytic graphite film.

The lower surface of resin sheet 11 is pressed against the upper surfaces of component 17 and circuit board 16 so as to bond sheet 15 to circuit board 16 mounted with component 17. Resin sheet 11 is plastically deformed and bonded to component 17 as well as to an exposed area, which includes no electronic components, of the upper surface of circuit board 16.

Thermally conductive resin sheet 11 is plastically deformed so as to have the following portions, on a side opposite to a side to which film 12 is bonded; first portion 11A in contact with the component side of circuit board 16, second portion 11B in contact with the entire upper surface of component 17, and third portion 11C in contact with at least a half of the lateral sides of component 17.

Resins, which generally have elasticity, could be bonded to the upper surface of component 17, but could not be sufficiently bonded to the lateral sides due to springback. In contrast, in heat dissipation structure 18, resin sheet 11 is made of plastically deformable resin and therefore can be sufficiently bonded to the lateral sides of component 17, thereby providing a large contact area. In heat dissipation structure 18, most of the heat generated in component 17 propagates from the upper surface of component 17 to thermally conductive film 12 via resin sheet 11. In addition, part of the heat propagates from the lateral sides of component 17 to resin sheet 11 and then to circuit board 16. Thus, the heat is released or propagated much more efficiently than in the conventional thermally conductive sheets.

As described above, heat dissipation structure 18 includes heat dissipation sheet 15 formed by bonding thermally conductive resin sheet 11 and thermally conductive film 12 together. Resin sheet 11 is bonded to the surfaces of circuit board 16 and component 17 so as to follow their outer shapes, thus providing a large contact area. Film 12 has a high thermal conductivity in the surface direction. As a result, heat dissipation structure 18 has excellent heat dissipation characteristics. Furthermore, heat-generating component 17 mounted on circuit board 16 can be easily removed by peeling heat dissipation sheet 15 off from circuit board 16 having heat-generating component 17 mounted thereon. Therefore, if heat-generating component 17 mounted on circuit board 16 is found to be defective, it can be easily replaced.

Thermally conductive resin sheet 11 before being bonded to circuit board 16 preferably has a thickness larger than the height of heat-generating component 17. This allows resin sheet 11 to be plastically deformed and to be in contact with the upper surface of circuit board 16, so that heat can propagate from the upper surface of circuit board 16 directly to heat dissipation sheet 15.

The portion, which is in contact with the upper surface of component 17, of resin sheet 11 is plastically deformed to have a thickness T1 of, for example, 0.4 mm. The small thickness T1 allows heat to quickly propagate from component 17 to film 12. When the thickness T1 is more than 0 mm and 0.5 mm or less, excellent heat dissipation characteristics are ensured in actual practice.

Heat dissipation sheet 15 can be bonded to circuit board 16 by applying pressure to them with a roller or by pressing the upper surface of sheet 15 using an elastic body. In either case, it is preferable to provide protective film 14 on the upper surface of thermally conductive film 12. Film 14 preferably has a higher tensile strength than film 12 so as to reduce the damage of heat dissipation sheet 15 when pressure is applied to the circuit board.

In the exemplary embodiment, the directional terms such as “upper surface” and “lower surface” indicate relative positional relationship between the circuit board and/or components included in the heat dissipation sheet, and do not indicate absolute directions such as vertical direction.

### INDUSTRIAL APPLICABILITY

The heat dissipation sheet and the heat dissipation structure including the sheet according to the present invention are industrially useful because they efficiently release or propagate heat generated in the heat-generating component, and also allow easy maintenance of the electronic components mounted on a printed circuit board.

### REFERENCE MARKS IN THE DRAWINGS

11 thermally conductive resin sheet

11A first portion

11B second portion

11C third portion

12 thermally conductive film

13 double-sided adhesive tape

14 protective film

15 heat dissipation sheet

16 printed circuit board

17 heat-generating component

18 heat dissipation structure

1. A heat dissipation sheet comprising:
a thermally conductive resin sheet formed of styrene polymer and plastically deformable at 25° C.; and
a thermally conductive film bonded to the thermally conductive resin sheet and having a higher thermal conductivity than the thermally conductive resin sheet.

2. The heat dissipation sheet according to claim 1, wherein
the thermal conductivity of the thermally conductive resin sheet is at least 1 W/m·K, and
the thermal conductivity in a surface direction of the thermally conductive film is at least 100 W/m·K.

3. The heat dissipation sheet according to claim 1, wherein the thermally conductive film is a graphite film.

4. The heat dissipation sheet according to claim 1, wherein the thermally conductive resin sheet has a thickness of 0.5 mm or more and 2 mm or less.

5. The heat dissipation sheet according to claim 1, further comprising a protective film provided on a side opposite to a side to which the thermally conductive resin sheet is bonded, of the thermally conductive film.

6. A heat dissipation structure comprising:
a printed circuit board;
an electronic component mounted on a component side of the printed circuit board; and
a heat dissipation sheet provided on the printed circuit board so as to cover the electronic component,
wherein
the heat dissipation sheet includes:
a thermally conductive resin sheet formed of styrene polymer and plastically deformable at 25° C.; and
a thermally conductive film bonded to the thermally conductive resin sheet and having a higher thermal conductivity than the thermally conductive resin sheet,
wherein the thermally conductive resin sheet has first to third portions on a side opposite to a side to which the thermally conductive film is bonded,
the first portion is in contact with the component side of the printed circuit board,
the second portion is in contact with an entire upper surface of the electronic component, and
the third portion is in contact with at least a half of lateral sides of the electronic component.

7. The heat dissipation structure according to claim 6, wherein the thermally conductive resin sheet, before being bonded to the printed circuit board, has a thickness larger than a height of the electronic component.

8. The heat dissipation structure according to claim 6, wherein the thermally conductive resin sheet has a thickness of more than 0 mm and 0.5 mm or less in the second portion.

9. The heat dissipation structure according to claim 6, wherein
the thermal conductivity of the thermally conductive resin sheet is at least 1 W/m·K, and
the thermal conductivity in a surface direction of the thermally conductive film is at least 100 W/m·K.

10. The heat dissipation structure according to claim 6, wherein the thermally conductive film is a graphite film.

11. The heat dissipation structure according to claim 6, wherein the thermally conductive resin sheet has a thickness of 0.5 mm or more and 2 mm or less.

12. The heat dissipation structure according to claim 6, further comprising a protective film provided on a side opposite to a side to which the thermally conductive resin sheet is bonded, of the thermally conductive film.
